(19) United States
(12) Patent Application Publication
(10) Pub. No.: US 2023/0343598 A1
(43) Pub. Date: Oct. 26, 2023

(54) Method For Improving Etch Rate And Critical Dimension Uniformity When Etching High Aspect Ratio Features Within A Hard Mask Layer

(71) Applicant: Tokyo Electron Limited, Tokyo (JP)

(72) Inventors: Shihsheng Chang, Albany, NY (US); Andrew Metz, Albany, NY (US); Yun Han, Albany, NY (US); Minjoon Park, Albany, NY (US); Kai-Hung Yu, Albany, NY (US); Eric Chih-Fang Liu, Albany, NY (US)

(21) Appl. No.: 17/726,992

(22) Filed: Apr. 22, 2022

(51) Int. Cl. H01L 21/308; H01L 21/033; H01L 21/02; H01L 21/311; H01L 21/3213; H01L 25/065

(52) U.S. Cl. CPC H01L 21/3081; H01L 21/0337; H01L 21/0228; H01L 21/31144; H01L 21/32139; H01L 25/0657; H01L 27/11556

(57) ABSTRACT

Various embodiments of stacked structures, process steps and methods are provided herein for etching high aspect ratio features (e.g., contact holes, vias, trenches, etc.) within a stacked structure comprising a hard mask layer, which is formed above and in contact with one or more underlying layers. At least one etch stop layer (ESL) is provided within the hard mask layer to divide the hard mask layer into two or more distinct portions. When the stacked structure is subsequently etched to form high aspect ratio features within the hard mask layer, such as contact holes or vias that extend through the hard mask layer, the ESL(s) included within the hard mask layer improve etch rate and critical dimension (CD) uniformity of the features etched within the hard mask layer.

### BACKGROUND

The present disclosure relates to the processing of substrates. In particular, it provides methods for improving etch rate and critical dimension (CD) uniformity during an etching process.

Semiconductor device formation typically involves a series of manufacturing techniques related to the formation, patterning, and removal of layers of material on a substrate. To meet the physical and electrical specifications of current and next generation semiconductor devices, process flows are being requested to reduce feature size while maintaining structure integrity for various patterning processes.

Three dimensional (3D) stacked semiconductor memory, such as 3D-NAND flash memory or the like, includes a multilayer vertical stack in which different types of layers are laminated together in an alternating fashion. In some cases, a large number of layers (e.g., up to 192 layers or more) may be included within the multilayer vertical stack. After the vertical stack is formed on a base layer (e.g., a semiconductor substrate), a high aspect ratio (HAR) etch process is performed to form deep holes (or “channels”) that extend from the top of the vertical stack to the base layer. The channels formed within the vertical stack enable individual memory cells of a 3D-NAND flash memory to connect with one another in the vertical stack. Each channel formed within the vertical stack must be parallel and uniform. To achieve this, the etch process used to form the channels must be carefully controlled.

Plasma etching is typically used to form the deep holes within the vertical stack of a 3D-NAND flash memory device. As the number of layers in the vertical stack increase, the aspect ratio (AR) of the holes etched within the stack increases. This results in a high aspect ratio (HAR) etch process, in which etch rate and critical dimension (CD) variation often occurs. Before the vertical stack can be etched, a hard mask (HM) layer is deposited onto the vertical stack to stabilize the stack during the HAR etch process. After the hard mask layer is deposited, a number of overlying layers, such as a photoresist (PR) layer, an antireflective coating (ARC) layer, etc., are formed on top of the hard mask layer and etched to provide a pattern of holes. Another etch process is performed to etch the hard mask layer, so that the pattern of holes can be transferred to the vertical stack.

In 3D NAND flash memory devices, a relatively thick (e.g., a few micrometers) amorphous carbon layer (ACL) is often used as a hard mask material for the vertical stack etch step, due to its good etch selectivity to dielectric. Like the vertical stack etch step, the ACL etch is a HAR etch process, which also suffers from etch rate and CD variations. This is illustrated and described below with respect to FIGS. 1A-1C (Prior Art) and FIGS. 2A-2F (Prior Art).

FIGS. 1A-1C provide cross-section views through a stacked structure, illustrating a conventional etch process 100 used to etch features (e.g., contact holes or vias) within a hard mask layer of the stacked structure. It is noted that the cross-section views shown in FIGS. 1A-1C are in a first direction perpendicular to the features being formed in the hard mask layer deposited on the vertical stack. In the conventional etch process 100 shown in FIGS. 1A-1C, a stacked structure comprising a variety of layers is formed on a base layer 105 (e.g., a semiconductor substrate, such as a wafer). These layers include, but are not limited to, a multilayer vertical stack 110, an amorphous carbon layer (ACL) hard mask layer 115 deposited on the multilayer vertical stack 110, and one or more overlying layers 120 formed on top of the ACL hard mask layer 115. It is recognized that the layers 105, 110, 115 and 120 shown in the FIGS. 1A-1C are not drawn to scale. It is further recognized that FIGS. 1A-1C illustrate two different portions of a wafer: a first portion (a) having a slower etch rate (ER) and a second portion (b) having a faster ER.

Although not depicted as such in FIG. 1A, the multilayer vertical stack 110 formed on the base layer 105 includes alternating laminated layers. When used within a 3D NAND flash memory device, the multilayer vertical stack 110 includes alternating layers of dielectric and conductive material. A large number of layers is typically included within the multilayer vertical stack 110. After the multilayer vertical stack 110 is formed on base layer 105, a relatively thick ACL hard mask layer 115 is formed on top of the multilayer vertical stack 110. Next, a number of overlying layers 120, such as a dielectric layer, an antireflective coating (ARC) layer, a photoresist (PR) layer, etc., are formed on top of the ACL hard mask layer 115 and etched to provide a pattern of holes.

In the stacked structure shown in FIG. 1A, an etch process is performed to etch or open a pattern of holes within the one or more overlying layers 120 formed on top of the ACL hard mask layer 115. For the sake of drawing clarity, FIG. 1A illustrates a first hole 125 formed within the overlying layer(s) 120 in a first region (a) of the wafer, and a second hole 130 formed within the overlying layer(s) 120 in a second region (b) of the wafer. The etch process used to etch or open the holes within the one or more overlying layers 120 may be implemented as one or more plasma etch process steps. However, other etch processes could also be used to open the holes within the one or more overlying layers 120.

After the pattern of holes is formed within the overlying layer(s) 120, another etch process is performed to transfer the pattern of holes to the ACL hard mask layer 115. The etch process used to etch the ACL hard mask layer 115 may be implemented as a single plasma etch process step, the progress of which is shown in FIGS. 1B and 1C.

As shown in FIG. 1B, the hole 130 formed within the second region (b) of the wafer is etched faster than the hole 125 formed within the first region (a) of the wafer. In other words, the etch rate of the ACL etch process step is faster in the second region (b) than the first region (a) of the wafer. This may be due to a variety of factors, as discussed below in reference to FIGS. 2A-2F. Due to the faster etch rate in the second region (b) of the wafer, the hole 130 extends down into the multilayer vertical stack 110 when over etching is performed to complete etching of the hole 125.

The etch rate differences shown in FIGS. 1B and 1C may occur in a variety of different situations. For example, different etch rates may occur in different portions of the wafer, due to differences in plasma distribution across the wafer. As shown in FIG. 2A, the hole 140 formed within the edge region (b) of the wafer is etched faster than the hole 135 formed within the center region (a) of the wafer. This leads to a difference in critical dimension (CD) between the holes 135 and 140, as shown in FIG. 2B. Etch rate differences may also occur due to differences in loading and aspect ratio. As shown in FIG. 2C, for example, the hole 150 formed within an isolated region (b) of the wafer is etched faster than the holes 145 formed within a densely packed region (a) of the wafer. This also leads to CD differences, as shown in FIG. 2D. Finally, FIG. 2E illustrates how aspect ratio dependent etching (ARDE) causes etch rate non-uniformity. As shown in FIG. 2E, the hole 160 having a larger aspect ratio (b) is etched faster than the hole 155 having a smaller aspect ratio (a). While the difference in aspect ratio inherently results in CD differences, such differences are exasperated by the difference in etch rate.

### SUMMARY

The present disclosure provides various embodiments of stacked structures, process steps and methods for etching high aspect ratio (HAR) features (e.g., contact holes, vias, trenches, etc.) within hard mask layers to reduce or eliminate problems, such as etch rate and critical dimension (CD) non-uniformity, that occur during conventional HAR etch processes. A stacked structure in accordance with the present disclosure may generally include a hard mask layer, which is formed above and in contact with one or more underlying layers formed on a semiconductor substrate, such as a wafer. At least one etch stop layer (ESL) is provided within the hard mask layer described herein to divide the hard mask layer into two or more distinct portions. In some embodiments, the hard mask layer may be a relatively thick (e.g., about 1 μm to 4 μm thick) carbon-containing hard mask layer.

When the stacked structure is subsequently etched to form high aspect ratio features within the hard mask layer, such as contact holes or vias that extend through the hard mask layer, the etch stop layer(s) included within the hard mask layer ensure that etching stops on each etch stop layer. This ensures that features etched within faster etch rate (ER) regions of the wafer stop on each etch stop layer, and allows features etched within slower ER regions to catch up to the etch stop layer, before a break through etch process step is performed to remove the etch stop layer and etching of the hard mask layer resumes.

The etch stop layer(s) included within the hard mask layer improve etch rate uniformity across the substrate by enabling features etched within the faster ER regions and the slower ER regions to proceed from the same etch depth (i.e., the depth at which a given etch stop layer is formed within the hard mask layer) when etching resumes. In some embodiments, multiple etch stop layers may be provided at various depths within the hard mask layer to further improve etch rate uniformity across the substrate. Critical dimension (CD) variation is inherently improved by improving the etch rate uniformity across the substrate. In some embodiments, CD uniformity may be further improved by depositing a passivation layer onto sidewalls of the features being etched after the features within the slower ER regions reach each etch stop layer. Other advantages and implementations can also be achieved while still taking advantage of the process techniques described herein.

The techniques described herein may be used to etch HAR features within a wide variety of hard mask layers. In some embodiments, the hard mask layer may comprise a relatively thick (e.g., about 1 μm to 4 μm thick) amorphous carbon layer (ACL) hard mask layer, which is utilized to etch a pattern of features within one or more underlying layers. An ACL hard mask layer may be utilized for patterning a wide variety of underlying layers. In some embodiments, for example, the underlying layers may include a dielectric layer. In other embodiments, the underlying layers may include a multilayer vertical stack of alternating layers of dielectric and conductive material. In one particular embodiment, the multilayer vertical stack may be part of a three-dimensional (3D) stacked semiconductor memory, such as a 3D NAND flash memory device or the like.

According to a first embodiment, a method is provided that utilizes the techniques described herein to improve etch rate and CD uniformity when etching high aspect ratio features within a hard mask layer of a stacked structure. In some embodiments, the method may begin by forming a stacked structure on a substrate, wherein said forming the stacked structure includes: (a) forming a hard mask layer above and in contact with one or more underlying layers; and (b) forming at least one etch stop layer within the hard mask layer to divide the hard mask layer into two or more distinct portions. The method may further include performing multiple etch processes to etch a plurality of features within the hard mask layer. The plurality of features etched within the hard mask layer may include a first subset of features and a second subset of features, which etch at a faster rate than the first subset of features. In the first embodiment of the method, said forming the at least one etch stop layer within the hard mask layer improves etch rate and critical dimension (CD) uniformity of the features etched within the hard mask layer by ensuring that an etch depth of the first subset of features catches up to an etch depth of the second subset of features before the at least one etch stop layer is removed and etching of the hard mask layer resumes.

In some embodiments, said forming a stacked structure may include forming a first etch stop layer within the hard mask layer, wherein the first etch stop layer divides the hard mask layer into two distinct portions. In such embodiments, said performing multiple etch processes may include: (a) performing a first etch process step to etch the plurality of features within a first portion of the hard mask layer, wherein said performing the first etch process step continues until the first subset of features reaches the first etch stop layer; (b) performing a second etch process step to remove the first etch stop layer once etching of the first subset of features reaches the first etch stop layer; and (c) performing a third etch process step to etch the plurality of features within a second portion of the hard mask layer, wherein etching of the first subset of features and the second subset of features proceeds from the same etch depth when the third etch process step begins.

In some embodiments, said performing the second etch process step to remove the first etch stop layer may cause a passivation layer to be sputter deposited onto sidewalls of the plurality of features. In other embodiments, the method may further include depositing a passivation layer onto sidewalls of the plurality of features via atomic layer deposition (ALD) after performing the second etch process step and before performing the third etch process step.

In some embodiments, the method may continue the third etch process step until etching of the first subset of features reaches the one or more underlying layers. In such embodiments, forming the first etch stop layer within the hard mask layer may reduce CD differences between the features by approximately 50% compared to conventional etch processes that etch features within a similar hard mask layer without forming the first etch stop layer within the hard mask layer.

In some embodiments, said forming a stacked structure may include forming a first etch stop layer and a second etch stop layer within the hard mask layer, wherein the first etch stop layer and the second etch stop layer divide the hard mask layer into three distinct portions. In such embodiments, said performing multiple etch processes may further include: (d) continuing the third etch process step until etching of the first subset of features reaches the second etch stop layer; (e) performing a fourth etch process step to remove the second etch stop layer once etching of the first subset of features reaches the second etch stop layer; and (f) performing a fifth etch process step to etch the plurality of features within a third portion of the hard mask layer, wherein etching of the first subset of features and the second subset of features proceeds from the same etch depth when the fifth etch process step begins.

In some embodiments, said performing the fourth etch process step to remove the second etch stop layer may cause a passivation layer to be sputter deposited onto sidewalls of the plurality of features. In other embodiments, the method may further include depositing a passivation layer onto sidewalls of the plurality of features via atomic layer deposition (ALD) after performing the fourth etch process step and before performing the fifth etch process step.

In some embodiments, the method may continue the fifth etch process step until etching of the first subset of features reaches the one or more underlying layers. In such embodiments, forming the first etch stop layer and the second etch stop layer within the hard mask layer may reduce CD differences between the features by approximately 50-80% compared to conventional etch processes that etch features within a similar hard mask layer without forming the first etch stop layer and the second etch stop layer within the hard mask layer.

As noted above, the method may be used to improve etch rate and CD uniformity when etching high aspect ratio features within a hard mask layer of a stacked structure. In some embodiments, a thickness of the hard mask layer may range between 1 μm and 4 μm. In some embodiments, an aspect ratio of the features etched within the hard mask layer may range between 20 to 60.

In some embodiments, the hard mask layer may be a carbon-containing hard mask layer, which is formed above and in contact with the one or more underlying layers. In one embodiment, the one or more underlying layers may include a dielectric layer, and the carbon-containing hard mask layer may be formed above and in contact with the dielectric layer. In another embodiment, the one or more underlying layers may include a multilayer vertical stack of alternating layers of dielectric material and conductive material, and the carbon-containing hard mask layer may be formed above and in contact with a dielectric material layer of the multilayer vertical stack. In some embodiments, the carbon-containing hard mask layer may be an amorphous carbon layer (ACL) hard mask layer. Alternatively, the hard mask layer may include other carbon-containing hard mask layers (such as, e.g., an Advanced Patterning Film, APF, commercially available from Applied Materials) and other hard mask materials that exhibit good etch selectivity to dielectric.

According to a second embodiment, another method is provided that utilizes the techniques described herein to improve etch rate and CD uniformity when etching a pattern of contact holes within a stacked structure included within a three-dimensional (3D) stacked semiconductor memory, such as a 3D-NAND Flash memory device or the like. In some embodiments, the method may begin by forming the stacked structure on a substrate, wherein said forming the stacked structure includes: (a) forming a multilayer vertical stack comprising alternating layers of dielectric material and conductive material; (b) forming an amorphous carbon layer (ACL) hard mask layer above and in contact with a dielectric material layer of the multilayer vertical stack; and (c) forming at least one etch stop layer within the ACL hard mask layer to divide the ACL hard mask layer into two or more distinct portions.

The method may further include performing multiple etch processes to etch a pattern of contact holes within the ACL hard mask layer. The pattern of contact holes etched within the ACL hard mask layer may include a first subset of contact holes and a second subset of contact holes, which etch at a faster rate than the first subset of contact holes. In the second embodiment of the method, forming the at least one etch stop layer within the ACL hard mask layer improves etch rate and critical dimension (CD) uniformity of the contact holes etched within the ACL hard mask layer by ensuring that an etch depth of the first subset of contact holes catches up to an etch depth of the second subset of contact holes before the at least one etch stop layer is removed and etching of the ACL hard mask layer resumes.

In some embodiments, said forming the stacked structure may include forming a first etch stop layer within the ACL hard mask layer, wherein the first etch stop layer divides the ACL hard mask layer into two distinct portions. In such embodiments, said performing multiple etch processes may include: (a) performing a first etch process step to etch the pattern of contact holes within a first portion of the ACL hard mask layer, wherein said performing the first etch process step continues until the first subset of contact holes reaches the first etch stop layer; (b) performing a second etch process step to remove the first etch stop layer once etching of the first subset of contact holes reaches the first etch stop layer; and (c) performing a third etch process step to etch the pattern of contact holes within a second portion of the ACL hard mask layer, wherein etching of the first subset of contact holes and the second subset of contact holes proceeds from the same etch depth when the third etch process step begins.

In some embodiments, said performing the second etch process step to remove the first etch stop layer may cause a passivation layer to be sputter deposited onto sidewalls of the first subset of contact holes and the second subset of contact holes. In other embodiments, the method may further include depositing a passivation layer onto sidewalls of the first subset of contact holes and the second subset of contact holes via atomic layer deposition (ALD) after performing the second etch process step and before performing the third etch process step.

In some embodiments, the method may continue the third etch process step until etching of the first subset of contact holes reaches the dielectric material layer of the multilayer vertical stack. In such embodiments, forming the first etch stop layer within the hard mask layer may reduce CD differences between the first subset of contact holes and the second subset of contact holes by approximately 50% compared to conventional etch processes that etch contact holes within a similar ACL hard mask layer without forming the first etch stop layer within the ACL hard mask layer.

Like the previous embodiment, the method disclosed in the second embodiment may be used to improve etch rate and CD uniformity when etching high aspect ratio features, such as contact holes, within a hard mask layer of a stacked structure. In some embodiments, a thickness of the hard mask layer may range between 1 μm and 4 μm. In some embodiments, an aspect ratio of the first subset of contact holes and the second subset of contact holes etched within the hard mask layer may range between 20 to 60.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1C (Prior Art) are cross-section views through a stacked structure, illustrating a conventional etch process used to etch high aspect ratio (HAR) features within a hard mask layer of the stacked structure.

FIGS. 2A and 2B (Prior Art) are cross-section and top-down views, respectively, illustrating the variations in etch rate and critical dimension (CD) produced across the substrate when the conventional etch process shown in FIGS. 1A-1C is used to etch the HAR features within the hard mask layer.

FIGS. 2C and 2D (Prior Art) are cross-section and top-down views, respectively, illustrating the variations in etch rate and CD produced when the conventional etch process shown in FIGS. 1A-1C is used to etch densely packed vs single features within the hard mask layer.

FIGS. 2E and 2F (Prior Art) are cross-section and top-down views, respectively, illustrating the variations in etch rate and CD produced when the conventional etch process shown in FIGS. 1A-1C is used to etch small aspect ratio (AR) features and large AR features within the hard mask layer.

FIGS. 3A-3F are cross-section views through a stacked structure, illustrating one embodiment of an etch process that may be used to etch HAR features within a hard mask layer of the stacked structure with improved etch rate and CD uniformity in accordance with the present disclosure.

FIG. 4 is a top-down view illustrating improvements in CD achieved when the etch process shown in FIGS. 3A-3F is used to etch HAR features within the hard mask layer.

FIG. 5 is a cross-section view through the stacked structure shown in FIG. 3D, illustrating a sputter effect of the etch process step used to remove the etch stop layer.

FIGS. 6A-6F are cross-section views through a stacked structure, illustrating another embodiment of an etch process that may be used to etch HAR features within a hard mask layer of the stacked structure with improved etch rate and CD uniformity in accordance with the present disclosure.

FIGS. 7 and 8 illustrate additional embodiments of a stacked structure in which two etch stop layers are formed within the hard mask layer.

FIG. 9 illustrates an embodiment of a stacked structure in which three etch stop layers are included within the hard mask layer.

FIG. 10 is a flowchart diagram illustrating one embodiment of a method that utilizes the techniques described herein to improve etch rate and CD uniformity when etching high aspect ratio features within a hard mask layer.

FIG. 11 is a flowchart diagram illustrating one embodiment of a method that utilizes the techniques described herein to improve etch rate and CD uniformity when etching a pattern of contact holes within a stacked structure included within a three-dimensional (3D) stacked semiconductor memory.

FIG. 12 illustrates an exemplary processing system which may be utilized to perform the techniques described herein.

### DETAILED DESCRIPTION

The present disclosure provides various embodiments of stacked structures, process steps and methods for etching high aspect ratio (HAR) features (e.g., contact holes, vias, trenches, etc.) within hard mask layers to reduce or eliminate problems, such as etch rate and critical dimension (CD) non-uniformity, that occur during conventional HAR etch processes. A stacked structure in accordance with the present disclosure may generally include a hard mask layer, which is formed above and in contact with one or more underlying layers formed on a semiconductor substrate, such as a wafer. At least one etch stop layer (ESL) is provided within the hard mask layer described herein to divide the hard mask layer into two or more distinct portions. In some embodiments, the hard mask layer may be a relatively thick (e.g., about 1 μm to 4 μm thick) carbon-containing hard mask layer.

When the stacked structure is subsequently etched to form high aspect ratio features within the hard mask layer, such as contact holes or vias that extend through the hard mask layer, the etch stop layer(s) included within the hard mask layer ensure that etching stops on each etch stop layer. This ensures that features etched within faster etch rate (ER) regions of the wafer stop on each etch stop layer, and allows features etched within slower ER regions to catch up to the etch stop layer, before a break through etch process step is performed to remove the etch stop layer and etching of the hard mask layer resumes.

The etch stop layer(s) included within the hard mask layer improve etch rate uniformity across the substrate by enabling features etched within the faster ER regions and the slower ER regions to proceed from the same etch depth (i.e., the depth at which a given etch stop layer is formed within the hard mask layer) when etching resumes. In some embodiments, multiple etch stop layers may be provided at various depths within the hard mask layer to further improve etch rate uniformity across the substrate. Critical dimension (CD) variation is inherently improved by improving the etch rate uniformity across the substrate. In some embodiments, CD uniformity may be further improved by depositing a passivation layer onto sidewalls of the features being etched after the features within the slower ER regions reach each etch stop layer. Other advantages and implementations can also be achieved while still taking advantage of the process techniques described herein.

The techniques described herein may be used to etch HAR features within a wide variety of hard mask layers. In some embodiments, the hard mask layer may comprise a relatively thick (e.g., about 1 μm to 4 μm thick) amorphous carbon layer (ACL) hard mask layer, which is utilized to etch a pattern of features within one or more underlying layers. An ACL hard mask layer may be utilized for patterning a wide variety of underlying layers. In some embodiments, for example, the underlying layers may include a dielectric layer. In other embodiments, the underlying layers may include a multilayer vertical stack of alternating layers of dielectric and conductive material. In one particular embodiment, the multilayer vertical stack may be part of a three-dimensional (3D) stacked semiconductor memory, such as a 3D NAND flash memory device or the like.

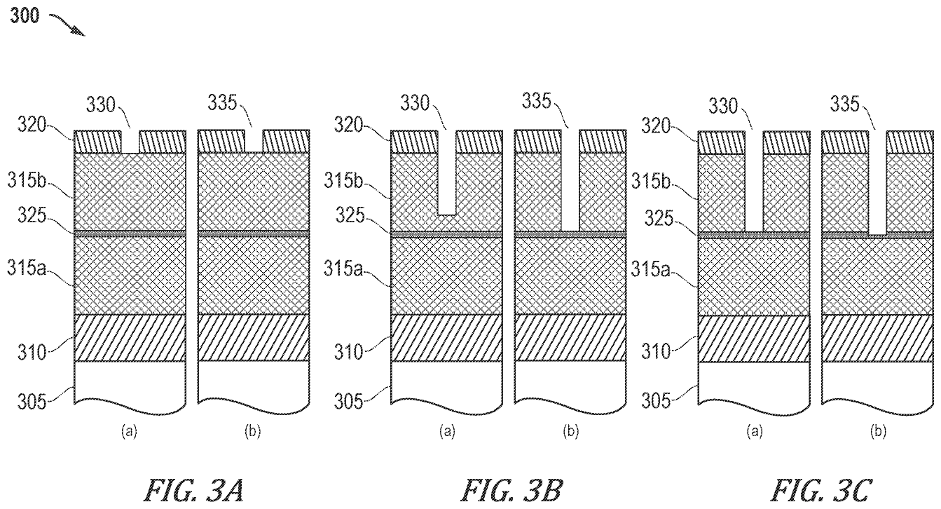

FIGS. 3A-3F illustrate one embodiment of an etch process 300 with improved etch rate and CD uniformity in accordance with the present disclosure. In FIGS. 3A-3E, cross-section views are provided for example embodiments of stacked structures and process steps that reduce or eliminate problems, such as etch rate and CD non-uniformity, that occur during conventional HAR etch processes. It is noted that these cross-section views are in a first direction perpendicular to the features (e.g., contact holes or vias) being formed in the stacked structure and show multiple features being formed within the stacked structure. In one embodiment, an inductively coupled plasma (ICP) etch process tool may be utilized to perform the etch process 300 shown in FIGS. 3A-3F.

For the sake of drawing clarity, the cross section views shown in FIGS. 3A-3E illustrate one hole being formed within a slower etch rate (ER) region and another hole being formed within a faster (ER) region of a stacked structure formed on a semiconductor substrate, such as a wafer. Although only one hole is illustrated within each region, it is recognized that the slower ER and faster ER regions of the wafer may each comprise one or more features. In some embodiments, differences in etch rate may inherently occur in the slower ER and faster ER regions due to loading (e.g., isolated vs. dense features), aspect ratio dependent etching (ARDE) and differences in plasma distribution across the wafer. For example, isolated features may be etched faster than densely packed features, large aspect ratio (AR) features may be etched faster than small AR features, and features formed near the edge may be etched faster than features formed near the center of the wafer. To overcome the etch rate differences induced by loading, ARDE and plasma distribution, one or more etch stop layers are provided within the hard mask layer described herein to improve etch rate and CD uniformity during the hard mask open step.

In some embodiments, the process steps shown in FIGS. 3A-3F can be used as part of a 3D memory fabrication process where the hard mask layer is opened to provide a pattern of holes to be transferred to a high aspect ratio multilayer vertical stack underlying the hard mask layer. It is recognized that the material layers and layer depths shown in FIGS. 3A-3F are not drawn to scale. In particular, the depth of the hard mask layer is exaggerated to illustrate the inventive concepts described herein, while the depth and material composition of the multilayer vertical stack is minimized to maintain focus on the hard mask layer. One skilled in the art would recognize that, in practice, the depth of a multilayer vertical stack utilized in 3D NAND flash memory applications would be much larger than the depth of the hard mask layer used to pattern the multilayer vertical stack.

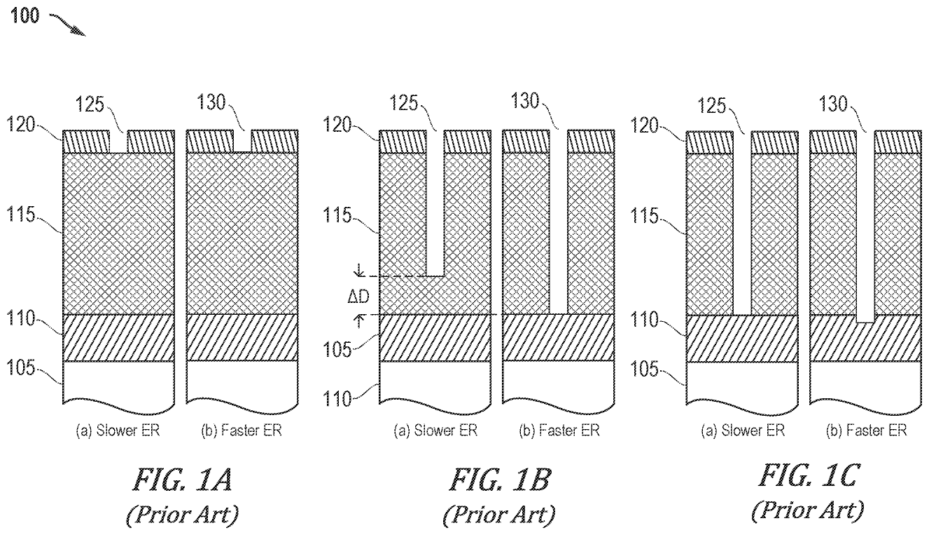

FIG. 3A illustrates a process step where a stacked structure has been formed on a base layer 305, such as a semiconductor substrate, and a pattern of holes (including holes 330 and 335) have been opened within the overlying layer(s) 320 at the top of the stacked structure. As shown in FIG. 3A, the stacked structure may generally include, but is not limited to, one or more underlying layers 310 formed on the base layer 305, a hard mask layer 315 formed on top of the underlying layer(s) 310, and one or more overlying layers 320 formed on top of the hard mask layer 315. Unlike the stacked structure shown in FIGS. 1A-1C, the stacked structure shown in FIG. 3A includes an etch stop layer (ESL) 325 within the hard mask layer 315 to divide the hard mask layer 315 into two distinct portions 315a and 315b. In some embodiments, the hard mask layer 315 may be an amorphous carbon layer (ACL) hard mask layer and the ESL 325 may include a variety of etch stop materials having good selectivity to ACL or other carbon-containing hard mask layer materials.

The hard mask layer 315 shown in FIG. 3A may be utilized for etching a wide variety of underlying layers 310. In some embodiments, the one or more underlying layers 310 may include a dielectric material (such as, e.g., an oxide), which is formed on a silicon substrate base layer 305. In other embodiments, the one or more underlying layers 310 may be implemented as a multilayer vertical stack comprising alternating layers of dielectric and conductive materials, such as for example, alternating layers of oxide and nitride (ONON), alternating layers of silicon oxide and polysilicon (OPOP), etc. In some embodiments, the stacked structure shown in FIG. 3A may be used within a 3D stacked semiconductor memory, such as a 3D NAND flash memory device or the like.

A wide variety of overlying layers 320 may be formed above the hard mask layer 315 and used to etch a pattern of holes within the hard mask layer. For example, the one or more overlying layers 320 shown in FIG. 3A may include a photoresist (PR) layer, an antireflective coating (ARC) layer, an organic dielectric layer (ODL) and a silicon oxynitride (SiON) layer. Other layers may also be included within the stacked structure, as is known in the art.

In one example embodiment, a stacked structure in accordance with the present disclosure may include a 15-60 nm PR layer, a 20-40 nm ARC layer, a 200-400 nm ODL, 100-400 nm SiON layer, a 1-4 μm hard mask layer 315, a 2-100 nm ESL 325 and a 6-11 μm underlying layer(s) 310, all of which is formed on a silicon substrate base layer 305. It is recognized that other layers may be used within the stacked structure, as is known in the art. A wide variety of materials may be used to form the individual layers included within the stacked structure. For example, the PR layer may include any photoresist used in 193 nm immersion technology, including positive tone or negative tone photoresist layers. The ARC layer may include a silicon-containing ARC (SiARC) or a bottom ARC (BARC). The ODL may include an organic planarization layer (OPL) ODL (commercially available from Shin-etsu Chemical, Co., Ltd). The hard mask layer 315 may include ACL or other carbon-containing hard mask materials. The underlying layer(s) 310 may include a dielectric, such as an oxide, or multilayer vertical stack of alternating conductive and dielectric layers, such as ONON or OPOP. It is recognized that, although an ACL hard mask layer 315 may be preferred for etching the underlying layer(s) 310, in some embodiments, one skilled in the art would recognize that other carbon-containing hard mask layers and other hard mask materials having good selectivity to dielectric may also be used.

In the stacked structure shown in FIG. 3A, a single ESL 325 is provided within the hard mask layer 315 to divide the hard mask layer 315 into two distinct, relatively equal portions 315a and 315b. A wide variety of materials may be used to form the ESL 325 included within hard mask layer 315. For example, ESL 325 may include an oxide, nitride, carbide, metal oxide, metal nitride, metal carbide, other dielectric material layer(s) or combinations of layers. In some embodiments, a deposition thickness of the ESL 325 may range between a few nm to 100 nm or more.

A wide variety of deposition techniques may be used to form the layers 310, 315a, 325, 315b and 320 included within the stacked structure shown in FIG. 3A. For example, these layers can be formed using one or more deposition processes including an atomic layer deposition (ALD) process, a chemical vapor deposition (CVD) process, a plasma enhanced CVD (PECVD) process, a physical vapor deposition (PVD) process, or other deposition processes or combinations of processes. Such processes may begin, for example, by depositing the underlying layer(s) 310 on the base layer 305.

Once the underlying layer(s) 310 are formed, a first deposition process step is performed to deposit the first portion 315a of the hard mask layer 315 onto the underlying layer(s) 310. After the first portion 315a of the hard mask layer 315 is formed, a second deposition process step is performed to deposit the ESL 325 onto the first portion 315a of the hard mask layer 315, followed by a third deposition process step to deposit the second portion 315b of the hard mask layer 315 onto the ESL 325. Additional deposition steps may then be performed to deposit the overlying layers 320 onto the second portion 315b of the hard mask layer 315. The deposition process steps used to form the layers 310, 315a, 325, 315b and 320 may be performed using the same (or different) deposition technique (e.g., ALD, CVD, etc.) and suitable process gases. Such techniques and process gases may be known to those skilled in the art.

Once the layers 310, 315a, 325, 315b and 320 are formed, one or more etch process steps may be performed to etch or open a pattern of holes within the one or more overlying layers 320 formed above the hard mask layer 315. For the sake of drawing clarity, FIG. 3A illustrates a first hole 330 formed within the overlying layer(s) 320 in a first region (a) of the wafer, and a second hole 335 formed within the overlying layer(s) 320 in a second region (b) of the wafer. The etch process used to etch or open the holes 330 and 335 within the one or more overlying layers 320 may be implemented as one or more plasma etch process steps. However, other etch processes could also be used to open the holes within the one or more overlying layers 320.

In the stacked structure shown in FIGS. 3B and 3C, a first etch process step is performed to extend the holes 330 and 335, which were previously formed within the overlying layer(s) 320, through the second portion 315b of the hard mask layer 315. As shown in FIG. 3B, the hole 335 formed within the second region (b) of the wafer is etched faster than the hole 330 formed within the first region (a) of the wafer. In other words, the etch rate of the first etch process is substantially faster in the second region (b) than in the first region (a) of the wafer. This difference in etch rate may be due to a variety of factors, including but not limited to, differences in plasma distribution across the wafer, differences in loading (e.g., isolated vs. dense features), and differences in aspect ratio (ARDE).

Although etch rate differences inherently exist, the ESL 325 included within the hard mask layer 315 ensures that the hole 335 formed within the second region (b) of the wafer (i.e., in the faster ER region) stops on the ESL 325, which enables the hole 330 formed within the first region (a) of the wafer (i.e., in the slower ER region) to catch up, as shown in FIG. 3C. Once the slower-etched hole 330 reaches the ESL 325, a second etch process step is performed to break through the ESL 325, as shown in FIG. 3D, before etching of the first portion 315a of the hard mask layer 315 resumes. By providing an ESL 325 between the first portion 315a and the second portion 315b of the hard mask layer 315, the etch process 300 ensures that the holes 330 and 335 proceed from the same depth (i.e., the depth at which the ESL 325 is formed within the hard mask layer 315) when etching resumes.

In the stacked structure shown in FIGS. 3E and 3F, a third etch process step is performed to extend the holes 330 and 335 through the first portion 315a of the hard mask layer 315. As shown in FIG. 3E, the hole 335 formed within the second region (b) of the wafer continues to etch at a faster rate than the hole 330 formed within the first region (a) of the wafer. The third etch process step continues until the slower-etched hole 330 reaches the underlying layer(s) 310, as shown in FIG. 3F. This results in a slight over-etch (or recess) of the faster-etched hole 335 into the underlying layer(s) 310.

Due to the faster etch rate, the hole 335 etched within the second region (b) of the wafer (i.e., in the faster ER region) reaches the underlying layer(s) 310 in FIG. 3E before the hole 330 etched the first region (a) of the wafer (i.e., in the slower ER region) in FIG. 3F. However, since etching of the hard mask layer 315 resumed at the same depth in FIG. 3D, the difference in etch depth (ΔD) between the features (i.e., hole 330 and hole 335) shown in FIG. 3E is much less than the difference in etch depth (ΔD) between the features (i.e., hole 125 and the hole 130) shown in FIG. 1B (Prior Art). In other words, the etch process 300 shown in FIGS. 3A-3F provides a more uniform etch rate across the wafer and reduces over-etching in faster ER regions than the conventional etch process 100 shown in FIGS. 1A-1C (Prior Art).

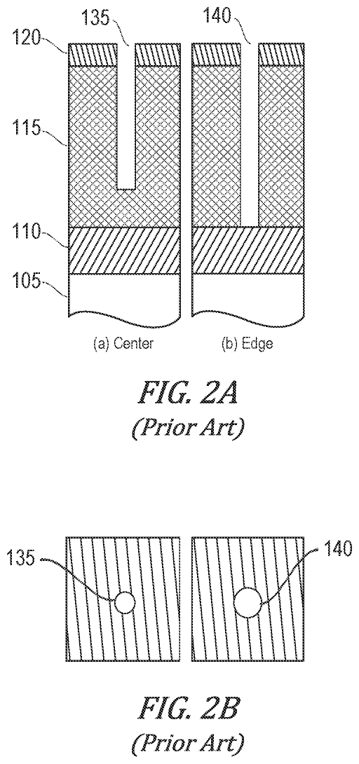

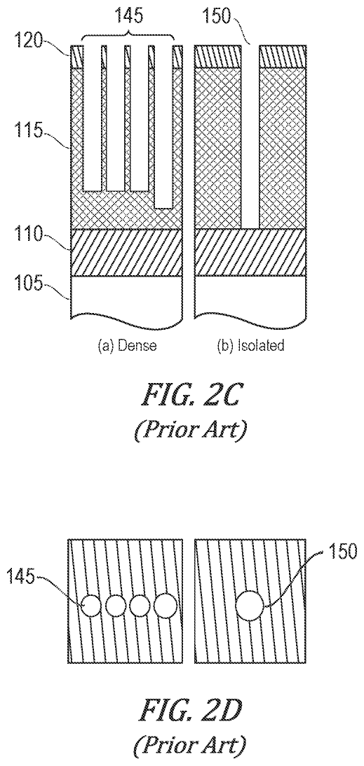

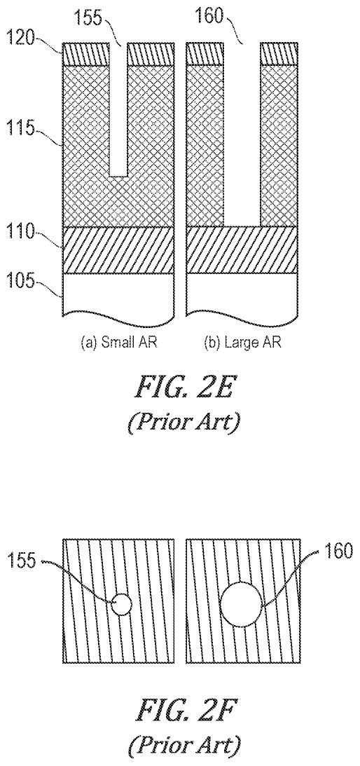

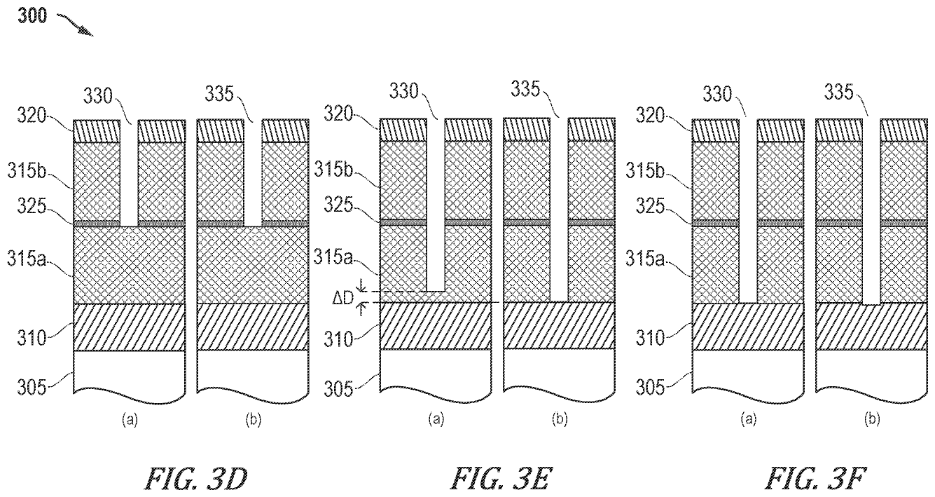

As described above in the background section, the conventional etch process 100 shown in FIGS. 1A-1C suffers from etch rate and CD non-uniformity, due to differences in plasma distribution across the wafer (FIGS. 2A-2B), differences in loading (FIGS. 2C-2D) and differences in aspect ratio (FIGS. 2E-2F). In contrast, the etch process 300 shown in FIGS. 3A-3F improves etch rate uniformity across the wafer by providing at least one ESL 325 within the hard mask layer 315. CD variation is inherently improved in the etch process 300 by improving the etch rate uniformity across the waver. For example, FIG. 4 illustrates the improved CD achieved when the etch process 300 shown in FIGS. 3A-3F is used to etch high aspect ratio features (such as contact holes and vias) within the hard mask layer 315.

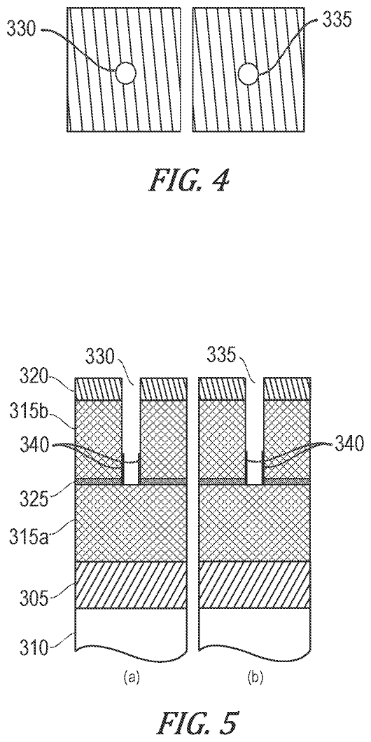

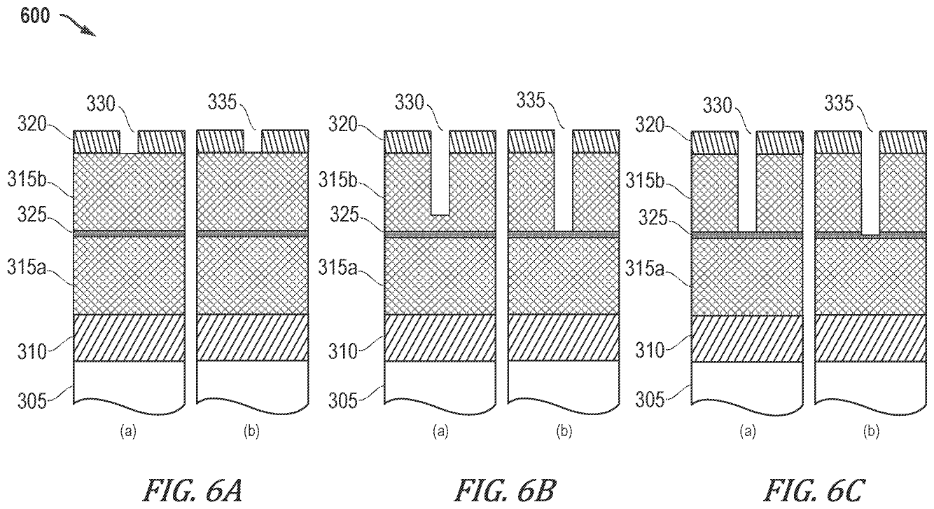

In some embodiments of the present disclosure, CD uniformity may be further improved by depositing a passivation layer onto the sidewalls of the features being etched within the hard mask layer after the features within the slower ER regions reach the ESL 325. In some embodiments, a passivation layer 340 may be deposited onto the sidewalls of the holes 330 and 335 via sputtering when the second etch process is performed to break through the ESL 325. This sputter effect is illustrated in FIG. 5 and is generally dependent on the material(s) used to implement the ESL 325 and the etch process conditions used to perform the break through step to remove the ESL 325. As shown in FIG. 5, some etch stop layer materials and etch process conditions may form a passivation layer 340 on lower portions of the sidewalls of the holes 330 and 335 by depositing sputtered etch stop layer materials onto the sidewalls. However, other etch stop layer materials and/or etch process conditions may not produce such a sputter effect. Thus, in other embodiments, an ALD process or a quasi-ALD process may be used to deposit a passivation layer 340 onto the sidewalls of the holes 330 and 335 after the second etch process is performed to break through the ESL 325 and before etching of the hard mask layer 315 resumes. This is illustrated in the etch process 600 shown in FIGS. 6A-6F.

FIGS. 6A-6F illustrate another embodiment of an etch process 600 with improved etch rate and CD uniformity in accordance with the present disclosure. Similar to the embodiment shown in FIGS. 3A-3F, cross-section views are provided in FIGS. 6A-6F for example embodiments of stacked structures and process steps that reduce or eliminate problems, such as etch rate and CD non-uniformity, that occur during conventional HAR etch processes. It is noted that the cross-section views shown in FIGS. 6A-6F are in a first direction perpendicular to the features (e.g., contact holes or vias) being formed in the stacked structure and show multiple features being formed within the stacked structure. In one embodiment, an inductively coupled plasma (ICP) etch process tool may be utilized to perform the etch process 600 shown in FIGS. 6A-6F.

FIG. 6A illustrates a process step where a stacked structure has been formed on a base layer 305, such as a semiconductor substrate, and a pattern of holes (including holes 330 and 335) have been opened within the overlying layer(s) at the top of the stacked structure. The stacked structure shown in FIG. 6A is identical to the stacked structure shown in FIG. 3A, and thus, may generally include, but is not limited to, one or more underlying layers 310 formed on a base layer 305, a first portion 315a of a hard mask layer 315 formed on the underlying layer(s) 310, an ESL 325 formed on the first portion 315a of the hard mask layer 315, a second portion 315b of the hard mask layer 315 formed on the ESL 325 and one or more overlying layers 320 formed on the second portion 315b of the hard mask layer 315. The layers of the stacked structure may generally be formed and configured as described above.

Similar to the process step shown in FIGS. 3B and 3C, FIGS. 6B and 6C illustrate a first etch process step that is performed to extend the holes 330 and 335, which were previously formed within the overlying layer(s) 320, through the second portion 315b of the hard mask layer 315. As before, the hole 335 formed within the second region (b) of the wafer etches at a faster rate than the hole 330 formed within the first region (a) of the wafer in FIGS. 6B and 6C due to, e.g., differences in plasma distribution across the wafer, loading or aspect ratio. However, the ESL 325 included within the hard mask layer 315 ensures that the faster-etched hole 335 stops on the ESL 325, which enables the slower-etched hole 330 to catch up, as shown in FIG. 6C. Once the slower-etched hole 330 reaches the ESL 325, a second etch process step is performed to break through the ESL 325 (in FIG. 6D) before etching of the first portion 315a of the hard mask layer 315 resumes. By providing an ESL 325 between the first portion 315a and the second portion 315b of the hard mask layer 315, the etch process 600 ensures that the holes 330 and 335 proceed from the same depth (i.e., the depth at which the ESL 325 is formed within the hard mask layer 315) when etching resumes.

The etch process 600 shown in FIGS. 6A-6D differs from the etch process 300 shown in FIGS. 3A-3D, in at least one respect, by utilizing an ALD process or a quasi-ALD process to deposit a passivation layer 340 onto the sidewalls of the hole 330 and the hole 335 after the second etch process is performed to break through the ESL 325 and before etching of the hard mask layer 315 resumes. In one embodiment, the ALD process or quasi-ALD process may use a silicon precursor gas to deposit a silicon-based passivation layer 340 onto the sidewalls of the hole 330 and the hole 335. One example of a silicon precursor gas suitable for use within an ALD process includes, but is not limited to, the silicon dioxide precursor diisopropylamino silane. Other precursor gases may also be utilized as is known in the art. The passivation layer 340 deposited onto the sidewalls protects the sidewalls of the holes 330 and 335 and limits CD growth during subsequent processing steps.

In the stacked structure shown in FIGS. 6E and 6F, a third etch process step is performed to extend the holes 330 and 335 through the first portion 315a of the hard mask layer 315. As shown in FIG. 6E, the hole 335 formed within the second region (b) of the wafer continues to etch at a faster rate than the hole 330 formed within the first region (a) of the wafer. The third etch process step continues until the slower-etched hole 330 reaches the underlying layer(s) 310 in FIG. 6F. This results in a slight over-etch (or recess) of the hole 335 into the underlying layer(s) 310.

Due to the faster etch rate, the hole 335 etched within the second region (b) of the wafer (i.e., in the faster ER region) reaches the underlying layer(s) 310 in FIG. 6E before the hole 330 etched within the first region (a) of the wafer (i.e., in the slower ER region) in FIG. 6F. However, since etching of the hard mask layer 315 resumed at the same depth in FIG. 6D, the difference in etch depth (ΔD) between the features (i.e., hole 330 and hole 335) shown in FIG. 6E is much less than the difference in etch depth (ΔD) between the features (i.e., hole 125 and the hole 130) shown in FIG. 1B (Prior Art). Thus, like the etch process 300 shown in FIGS. 3A-3F, the etch process 600 shown in FIGS. 6A-6F provides a more uniform etch rate across the wafer and reduces over-etching in faster ER regions than the conventional HAR etch process 100 shown in FIGS. 1A-1C. CD uniformity is improved in the etch process 600 shown in FIGS. 6A-6F by improving the etch rate uniformity across the wafer and by providing a passivation layer 340 on the sidewalls of the holes 330 and 335 formed within the stacked structure.

Various embodiments of an improved etch process for etching features within a stacked structure, and more specifically, for etching high aspect ratio features within a hard mask layer have been described above in reference to FIGS. 3-6. In some embodiments, the improved etch processes described herein may be particularly well suited for etching high aspect ratio features (e.g., features with aspect ratios between 20-60) within relatively thick (e.g., about 1 μm to 4 μm thick) hard mask layers. In one example implementation, the improved etch processes described herein may be used to etch ˜70 nm contact holes spaced ˜150 nm apart with a 1 μm-4 μm amorphous carbon layer (ACL) hard mask layer. By including at least one etch stop layer (ESL) within the ACL hard mask layer, the etch processes described herein improve etch rate uniformity and reduce or eliminate the CD differences that arise in conventional etch processes, due to differences in plasma distribution across the wafer (FIGS. 2A-2B), differences in loading (FIGS. 2C-2D) and differences in aspect ratio (FIGS. 2E-2F). By implementing and positioning a single etch stop layer 325 as shown in FIGS. 3A-3F and FIGS. 6A-6F, for example, the etch processes 300 and 600 described herein reduce over-etching (or recess depth) into the underlying layers 310 and CD differences produced between the high aspect ratio features by approximately 50% compared to conventional etch processes that attempt to etch high aspect ratio features within a hard mask layer of the same thickness without providing at least one etch stop layer within the hard mask layer.

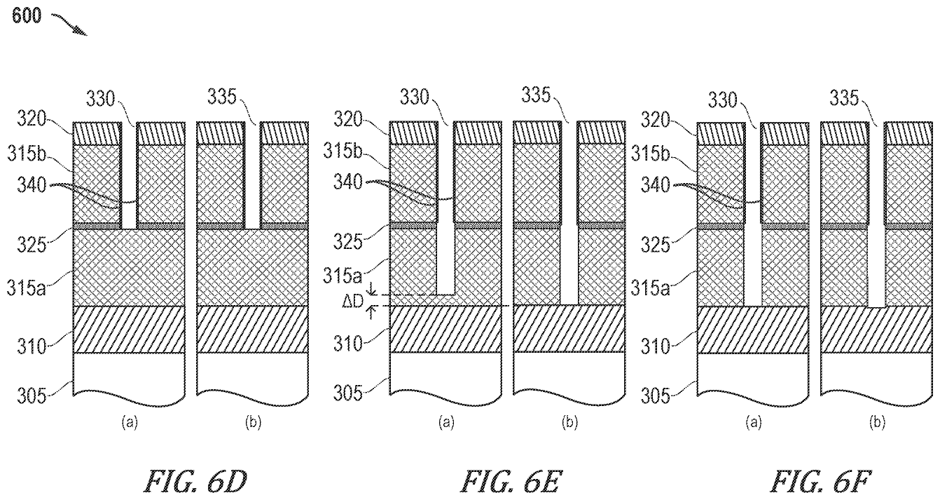

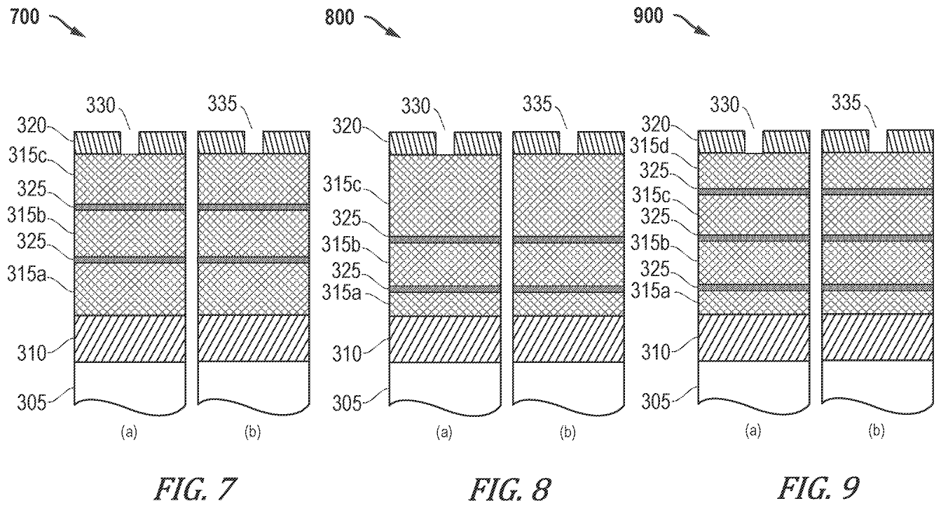

Although a single etch stop layer 325 is shown in FIGS. 3A-3F and FIGS. 6A-6F, the techniques described herein may also improve etch rate and CD uniformity by providing a plurality of etch stop layers (e.g., 1-3 etch stop layers) within the hard mask layer of a stacked structure. For example, FIGS. 7 and 8 illustrate various embodiments of a stacked structure in which two etch stop layers 325 are included within the hard mask layer 315. FIG. 9 illustrates an embodiment of a stacked structure in which three etch stop layers 325 are included within the hard mask layer 315. The etch stop layers 325 included within the hard mask layer 315 may be formed at a variety of different depths.

In the stacked structure 700 shown in FIG. 7, for example, the two etch stop layers 325 divide the hard mask layer 315 into three distinct and relatively equal portions 315a, 315b and 315c. When the stacked structure 700 shown in FIG. 7 is utilized, the etch processes described herein may reduce over-etching (or recess depth) into the underlying layers 310 and CD differences between the holes 330 and 335 by approximately 60-70% compared to conventional etch processes that attempt to etch high aspect ratio features within a hard mask layer of the same thickness without providing at least one etch stop layer within the hard mask layer.

In the stacked structure 800 shown in FIG. 8, the two etch stop layers 325 divide the hard mask layer 315 into three distinct, yet unequal portions 315a, 315b and 315c. Looking from the top of the stacked structure 800, a first ESL 325 is provided approximately in the middle of the hard mask layer 315, and a second ESL 325 is provided between the first ESL 325 and the underlying layers 310. When the stacked structure 800 shown in FIG. 8 is utilized, the etch processes described herein may reduce over-etching (or recess depth) into the underlying layers 310 by approximately 70-80%, and may reduce CD differences between the holes 330 and 335 by approximately 50%, compared to conventional etch processes that attempt to etch high aspect ratio features within a hard mask layer of the same thickness without providing at least one etch stop layer within the hard mask layer.

In the stacked structure 900 shown in FIG. 9, the three etch stop layers 325 divide the hard mask layer 315 into four distinct and relatively equal portions 315a, 315b, 315c and 315d. When the stacked structure 900 shown in FIG. 9 is utilized, the etch processes described herein may reduce over-etching (or recess depth) into the underlying layers 310 and CD differences between the holes 330 and 335 by approximately 70-80% compared to conventional etch processes that attempt to etch high aspect ratio features within a hard mask layer of the same thickness without providing at least one etch stop layer within the hard mask layer.

The number of etch stop layers 325 ultimately included within the hard mask layer 315 may generally depend on a variety of factors including, for example, the thickness of the hard mask layer 315, the material utilized for the hard mask layer 315, the plasma etch process and chemistry, the plasma etch equipment utilized, the etch rates and uniformity of the etch process, etc. Although increasing the number of etch stop layers provides better etch rate and CD uniformity control, each additional etch stop layer included within the hard mask layer reduces throughput by requiring an additional break through etch process step to remove the etch stop layer. Thus, it may be generally desirable to limit the number of etch stop layers included to the minimum number that provides acceptable etch rate and CD control.

In the present disclosure, one or more etch stop layers (ESLs) are provided within a relatively thick (e.g., about 1 μm to 4 μm thick) hard mask layer to divide the hard mask layer into two or more distinct portions. When the stacked structure is subsequently etched to form high aspect ratio features within the hard mask layer, such as contact holes or vias that extend through the hard mask layer, the etch stop layer(s) provided within the hard mask layer ensure that etching stops on each etch stop layer. This ensures that features etched within faster etch rate (ER) regions of the wafer stop on each etch stop layer, and allows for features etched within slower ER regions to catch up to the etch stop layer, before a break through etch process step is performed to remove the etch stop layer and etching of the hard mask layer resumes. The etch stop layer(s) included within the hard mask layer improve etch rate uniformity across the wafer by enabling features etched within the faster ER regions and the slower ER regions to proceed from the same etch depth (i.e., the depth at which the etch stop layer is formed within the hard mask layer) when etching resumes. In some embodiments, multiple etch stop layers may be provided at various depths within the hard mask layer to further improve etch rate uniformity across the wafer. CD uniformity is improved in the embodiments described herein by improving etch rate uniformity across the wafer and/or by depositing a sidewall passivation layer (e.g., via sputtering, ALD or quasi-ALD) during, or immediately after, the break through etch process step is performed to remove each etch stop layer.

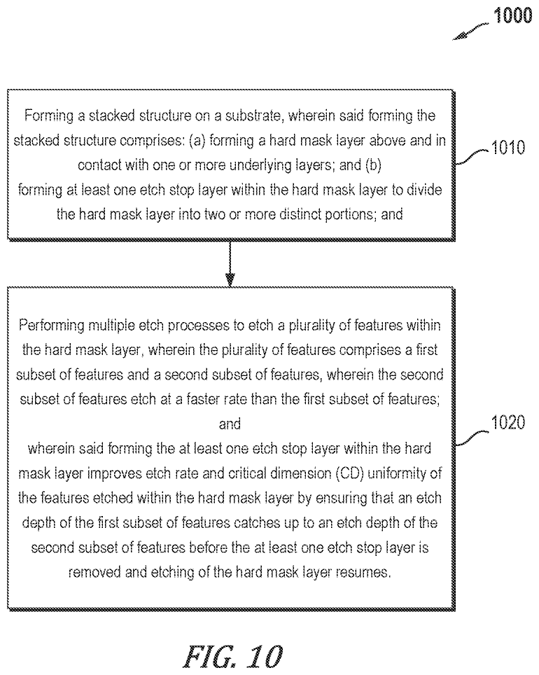

FIG. 10 is a flowchart diagram illustrating one embodiment of a method 1000 that utilizes the techniques described herein to improve etch rate and CD uniformity when etching high aspect ratio features within a hard mask layer of a stacked structure. In some embodiments, the method 1000 shown in FIG. 10 may begin by forming a stacked structure on a substrate (in step 1010), wherein said forming the stacked structure includes: (a) forming a hard mask layer above and in contact with one or more underlying layers; and (b) forming at least one etch stop layer within the hard mask layer to divide the hard mask layer into two or more distinct portions.

The method 1000 may further include performing multiple etch processes to etch a plurality of features within the hard mask layer (in step 1020). The plurality of features etched within the hard mask layer in step 1020 may include a first subset of features and a second subset of features, which etch at a faster rate than the first subset of features. In the method 1000 shown in FIG. 10, forming the at least one etch stop layer within the hard mask layer in step 1010 improves etch rate and critical dimension (CD) uniformity of the features etched within the hard mask layer by ensuring that an etch depth of the first subset of features catches up to an etch depth of the second subset of features before the at least one etch stop layer is removed and etching of the hard mask layer resumes.

In some embodiments, forming a stacked structure in step 1010 may include forming a first etch stop layer within the hard mask layer, wherein the first etch stop layer divides the hard mask layer into two distinct portions. In such embodiments, performing multiple etch processes in step 1020 may include: (a) performing a first etch process step to etch the plurality of features within a first portion of the hard mask layer, wherein said performing the first etch process step continues until the first subset of features reaches the first etch stop layer; (b) performing a second etch process step to remove the first etch stop layer once etching of the first subset of features reaches the first etch stop layer; and (c) performing a third etch process step to etch the plurality of features within a second portion of the hard mask layer, wherein etching of the first subset of features and the second subset of features proceeds from the same etch depth when the third etch process step begins.

In some embodiments, performing the second etch process step to remove the first etch stop layer may cause a passivation layer to be sputter deposited onto sidewalls of the plurality of features (as shown, e.g., in FIG. 5). In other embodiments, the method 1000 may further include depositing a passivation layer onto sidewalls of the plurality of features via atomic layer deposition (ALD) after performing the second etch process step and before performing the third etch process step (as shown, e.g., in FIG. 6D).

In some embodiments, the method 1000 may continue the third etch process step until etching of the first subset of features reaches the one or more underlying layers. In such embodiments, forming the first etch stop layer within the hard mask layer in step 1010 may reduce CD differences between the features by approximately 50% compared to conventional etch processes that etch features within a similar hard mask layer without forming the first etch stop layer within the hard mask layer.

In some embodiments, forming a stacked structure in step 1010 may include forming a first etch stop layer and a second etch stop layer within the hard mask layer, wherein the first etch stop layer and the second etch stop layer divide the hard mask layer into three distinct portions. In such embodiments, performing multiple etch processes in step 1020 may further include: (d) continuing the third etch process step until etching of the first subset of features reaches the second etch stop layer; (e) performing a fourth etch process step to remove the second etch stop layer once etching of the first subset of features reaches the second etch stop layer; and (f) performing a fifth etch process step to etch the plurality of features within a third portion of the hard mask layer, wherein etching of the first subset of features and the second subset of features proceeds from the same etch depth when the fifth etch process step begins.

In some embodiments, performing the fourth etch process step to remove the second etch stop layer may cause a passivation layer to be sputter deposited onto sidewalls of the plurality of features. In other embodiments, the method 1000 may further include depositing a passivation layer onto sidewalls of the plurality of features via atomic layer deposition (ALD) after performing the fourth etch process step and before performing the fifth etch process step.

In some embodiments, the method 1000 may continue the fifth etch process step until etching of the first subset of features reaches the one or more underlying layers. In such embodiments, forming the first etch stop layer and the second etch stop layer within the hard mask layer may reduce CD differences between the features by approximately 50-80% compared to conventional etch processes that etch features within a similar hard mask layer without forming the first etch stop layer and the second etch stop layer within the hard mask layer.

As noted above, the method 1000 shown in FIG. 10 may be used to improve etch rate and CD uniformity when etching high aspect ratio features within a hard mask layer of a stacked structure. In some embodiments, a thickness of the hard mask layer may range between 1 μm and 4 μm. In some embodiments, an aspect ratio of the features etched within the hard mask layer may be between 20-60.

In some embodiments, the hard mask layer may be a carbon-containing hard mask layer, which is formed above and in contact with the one or more underlying layers. In one embodiment, the one or more underlying layers may include a dielectric layer, and the carbon-containing hard mask layer may be formed above and in contact with the dielectric layer. In another embodiment, the one or more underlying layers may include a multilayer vertical stack of alternating layers of dielectric material and conductive material, and the carbon-containing hard mask layer may be formed above and in contact with a dielectric material layer of the multilayer vertical stack. In some embodiments, the carbon-containing hard mask layer may be an amorphous carbon layer (ACL) hard mask layer. Alternatively, the hard mask layer may include other carbon-containing hard mask layers (such as, e.g., an Advanced Patterning Film, APF, commercially available from Applied Materials) and other hard mask materials that exhibit good etch selectivity to dielectric.

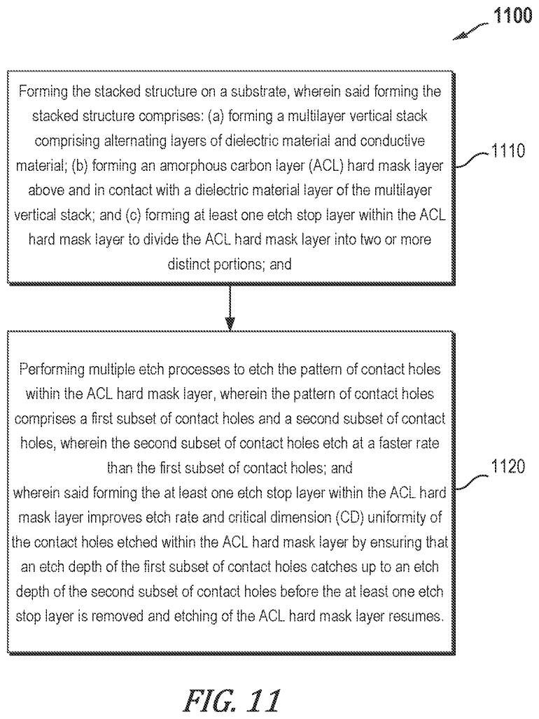

FIG. 11 is a flowchart diagram illustrating another embodiment of a method that utilizes the techniques described herein to improve etch rate and CD uniformity when etching a pattern of contact holes within a stacked structure included within a three-dimensional (3D) stacked semiconductor memory, such as a 3D-NAND Flash memory device or the like. In some embodiments, the method 1100 shown in FIG. 11 may begin by forming the stacked structure on a substrate (in step 1110), wherein said forming the stacked structure includes: (a) forming a multilayer vertical stack comprising alternating layers of dielectric material and conductive material; (b) forming an amorphous carbon layer (ACL) hard mask layer above and in contact with a dielectric material layer of the multilayer vertical stack; and (c) forming at least one etch stop layer within the ACL hard mask layer to divide the ACL hard mask layer into two or more distinct portions.

The method 1100 may further include performing multiple etch processes to etch a pattern of contact holes within the ACL hard mask layer (in step 1120). The pattern of contact holes etched within the ACL hard mask layer in step 1120 may include a first subset of contact holes and a second subset of contact holes, which etch at a faster rate than the first subset of contact holes. In the method 1100 shown in FIG. 11, forming the at least one etch stop layer within the ACL hard mask layer in step 1110 improves etch rate and critical dimension (CD) uniformity of the contact holes etched within the ACL hard mask layer by ensuring that an etch depth of the first subset of contact holes catches up to an etch depth of the second subset of contact holes before the at least one etch stop layer is removed and etching of the ACL hard mask layer resumes.

In some embodiments, forming the stacked structure in step 1110 may include forming a first etch stop layer within the ACL hard mask layer, wherein the first etch stop layer divides the ACL hard mask layer into two distinct portions. In such embodiments, performing multiple etch processes in step 1120 may include: (a) performing a first etch process step to etch the pattern of contact holes within a first portion of the ACL hard mask layer, wherein said performing the first etch process step continues until the first subset of contact holes reaches the first etch stop layer; (b) performing a second etch process step to remove the first etch stop layer once etching of the first subset of contact holes reaches the first etch stop layer; and (c) performing a third etch process step to etch the pattern of contact holes within a second portion of the ACL hard mask layer, wherein etching of the first subset of contact holes and the second subset of contact holes proceeds from the same etch depth when the third etch process step begins.

In some embodiments, performing the second etch process step to remove the first etch stop layer may cause a passivation layer to be sputter deposited onto sidewalls of the contact holes (as shown, e.g., in FIG. 5). In other embodiments, the method 1100 may further include depositing a passivation layer onto sidewalls of the contact holes via atomic layer deposition (ALD) after performing the second etch process step and before performing the third etch process step (as shown, e.g., in FIG. 6D).

In some embodiments, the method 1100 may continue the third etch process step until etching of the first subset of contact holes reaches the dielectric material layer of the multilayer vertical stack. In such embodiments, forming the first etch stop layer within the hard mask layer in step 1110 may reduce CD differences between the contact holes by approximately 50% compared to conventional etch processes that etch contact holes within a similar ACL hard mask layer without forming the first etch stop layer within the ACL hard mask layer.

Like the method 1000 shown in FIG. 10, the method 1100 shown in FIG. 11 may be used to improve etch rate and CD uniformity when etching high aspect ratio features, such as contact holes, within a hard mask layer of a stacked structure. In some embodiments, a thickness of the hard mask layer may range between 1 μm and 4 μm. In some embodiments, an aspect ratio of the contact holes etched within the hard mask layer may be between 20-60.

As noted above and shown in the drawings, various embodiments of stacked structures, process steps and methods for etching high aspect ratio features (e.g., contact holes, vias, trenches, etc.) are provided herein to reduce or eliminate problems, such as etch rate and critical dimension (CD) non-uniformity, that occur during conventional HAR etch processes. It is noted that the process steps and methods described herein may be utilized with a wide range of processing systems including plasma processing systems. For example, the process steps and methods may be utilized with plasma etch process systems, plasma deposition process systems, or any other plasma process system.

The deposition processes disclosed herein can be implemented using a wide variety of deposition processes and techniques. For example, the deposition processes used to form the layers of the stacked structure described herein can be implemented using chemical vapor deposition (CVD), plasma enhanced CVD (PECVD), physical vapor deposition (PVD), atomic layer deposition (ALD), and/or other deposition processes. For a plasma deposition process, a gas mixture including one or more precursor gases in combination with one or more inert gases (e.g., argon, nitrogen, etc.) can be used at a variety of pressure, power, flow and temperature conditions. The precursor gas(es) used during the various plasma deposition processes may generally depend on the layer being deposited. Lithography processes with respect to photoresist layers can be implemented using optical lithography, extreme ultra-violet (EUV) lithography, and/or other lithography processes.

The etch processes disclosed herein can also be implemented using a wide variety of etch processes and techniques, including plasma etch processes, discharge etch processes, and/or other desired etch processes. For example, plasma etch processes can be implemented using a plasma containing various processing gases (including reactive and inert gases). In addition, operating variables for process steps can be controlled to ensure that etch rate and CD target parameters are achieved during via and contact hole formation. The operating variables may include, for example, the chamber temperature, chamber pressure, flow rates of gases, frequency and/or power applied to electrode assembly in the generation of plasma, and/or other operating variables for the processing steps. Variations can also be implemented while still taking advantage of the techniques described herein.

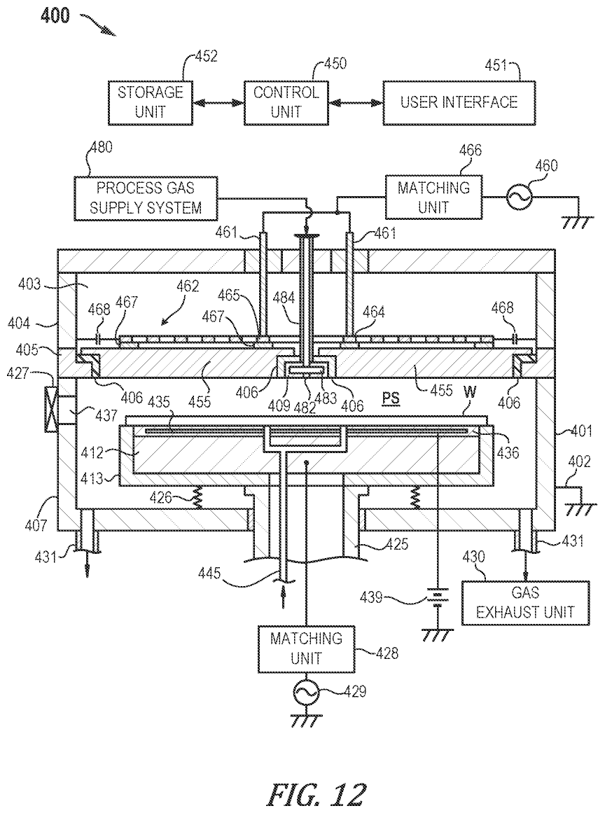

FIG. 12 illustrates one example processing system 400 that may be used to perform the techniques described herein. The processing system 400 shown in FIG. 12 is an inductively coupled plasma (ICP) processing tool. It will be recognized that the processing system 400 shown in FIG. 12 is merely one example of an ICP processing tool and a wide range of other inductively coupled plasma processing tools may be utilized to perform the techniques described herein. It is further recognized that the techniques described herein are not limited to an inductively coupled plasma processing system and other plasma processing systems may also be utilized.

This processing system 400 shown in FIG. 12 can be used for multiple operations including ashing, etching, and deposition. Plasma processing can be executed within processing chamber 401, which can be a vacuum chamber made of a metal such as aluminum or stainless steel. The processing chamber 401 is grounded such as by ground wire 402. The processing chamber 401 defines a processing vessel providing a process space PS for plasma generation. An inner wall of the processing vessel can be coated with alumina, yttria, or another protectant. The processing vessel can be cylindrical, square, column-shaped, etc.

At a lower, central area within the processing chamber 401, a susceptor 412 (which can be disc-shaped) can serve as a mounting table on which, for example, a substrate W to be processed (such as a semiconductor wafer) can be mounted. Substrate W can be moved into the processing chamber 401 through loading/unloading port 437 and gate valve 427. The susceptor 412 can be made of a conductive material. Susceptor 412 is provided thereon with an electrostatic chuck 436 for holding the substrate W. The electrostatic chuck 436 is provided with an electrode 435. Electrode 435 is electrically connected to DC power source 439 (direct current power source). The electrostatic chuck 436 attracts the substrate W thereto via an electrostatic force generated when DC voltage from the DC power source 439 is applied to the electrode 435 so that substrate W is securely mounted on the susceptor 412. The susceptor 412 can include an insulating frame 413 and be supported by support 425, which can include an elevation mechanism. The susceptor 412 can be vertically moved by the elevation mechanism during loading and/or unloading of the substrate W. A bellows 426 can be disposed between the insulating frame 413 and a bottom portion of the processing chamber 401 to surround support 425 as an airtight enclosure. Susceptor 412 can include a temperature sensor and a temperature control mechanism including a coolant flow path, a heating unit such as a ceramic heater or the like (all not shown) that can be used to control a temperature of the substrate W. A focus ring (not shown) can be provided on an upper surface of the susceptor 412 to surround the electrostatic chuck 436 and assist with directional ion bombardment.

A gas supply line 445, which passes through the susceptor 412, is configured to supply heat transfer gas to an upper surface of the electrostatic chuck 436. A heat transfer gas (also known as backside gas) such as helium (He) can be supplied between the substrate W and the electrostatic chuck 436 via the gas supply line 445 to assist in heating substrate W.

A gas exhaust unit 430 including a vacuum pump and the like can be connected to a bottom portion of the processing chamber 401 through gas exhaust line 431. The gas exhaust unit 430 can include a vacuum pump such as a turbo molecular pump configured to decompress the plasma processing space within the processing chamber 401 to a desired vacuum condition during a given plasma processing operation.

The processing system 400 can be horizontally partitioned into an antenna chamber 403 and a processing chamber 401 by a window 455. Window 455 can be a dielectric material, such as quartz, or a conductive material, such as metal. Embodiments in which the window 455 is metal, the window 455 can be electrically insulated from processing chamber 401 such as with insulators 406. In this example, the window 455 forms a ceiling of the processing chamber 401. In some embodiments, window 455 can be divided into multiple sections, with these sections optionally insulated from each other.

Provided between sidewall 404 of the antenna chamber 403 and sidewall 407 of the processing chamber 401 is a support shelf 405 projecting toward the inside of the processing apparatus. A support member 409 serves to support window 455 and also functions as a shower housing for supplying a processing gas. When the support member 409 serves as the shower housing, a gas channel 483, extending in a direction parallel to a working surface of a substrate W to be processed, is formed inside the support member 409 and communicates with gas injection openings 482 for injecting process gas into the process space PS. A gas supply line 484 is configured to be in communication with the gas channel 483. The gas supply line 484 defines a flow path through the ceiling of the processing chamber 401, and is connected to a process gas supply system 480 including a processing gas supply source, a valve system and the corresponding components. Accordingly, during plasma processing, a given process gas can be injected into the process space PS.

In antenna chamber 403, a high-frequency antenna 462 (radio frequency) is disposed above the window 455 so as to face the window 455, and can be spaced apart from the window 455 by a spacer 467 made of an insulating material. High-frequency antenna 462 can be formed in a spiral shape or formed in other configurations.

During plasma processing, a high frequency power having a frequency of, e.g., 13.56 MHz, for generating an inductive electric field can be supplied from a high-frequency power source 460 to the high-frequency antenna 462 via power feed members 461. A matching unit 466 (impedance matching unit) can be connected to high-frequency power source 460. The high-frequency antenna 462 in this example can have corresponding power feed portion 464 and power feed portion 465 connected to the power feed members 461, as well as additional power feed portions depending on a particular antenna configuration. Power feed portions can be arranged at similar diametrical distances and angular spacing. Antenna lines can extend outwardly from power feed portion 464 and power feed portion 465 (or inwardly depending on antenna configuration) to an end portion of antenna lines. End portions of antenna lines are connected to the capacitors 468, and the antenna lines are grounded via the capacitors 468. Capacitors 468 can include one or more variable capacitors.

With a given substrate is mounted within processing chamber 401, one or more plasma processing operations can be executed. By applying high frequency power to the high-frequency antenna 462, an inductive electric field is generated in the processing chamber 401, and processing gas supplied from the gas injection openings 482 is turned into a plasma by the inductive electric field. The plasma can then be used to process a given substrate such as by etching, ashing, deposition, etc.

High-frequency power source 429 (as second high-frequency power source) is connected to the susceptor 412 via a matching unit 428. The high-frequency power source 429 supplies a high frequency bias power having a frequency of, e.g., 3.2 MHz (or other frequency), to the mounting table during plasma processing. Applying high frequency bias power causes ions, in plasma generated in the processing chamber, to be attracted to the substrate W.

Components of the processing system 400 can be connected to, and controlled by, a control unit 450, which in turn can be connected to a corresponding storage unit 452 and user interface 451. Various plasma processing operations can be executed via the user interface 451, and various plasma processing recipes and operations can be stored in storage unit 452. Accordingly, a given substrate W can be processed within the processing chamber 401 with various microfabrication techniques.

The techniques described herein for etching a plurality of high aspect ratio features (e.g., contact holes or vias) within a hard mask layer may be accomplished with a variety of etch process conditions (power, pressure, temperature, gasses, flow rates, etc.). An exemplary process recipe is described herein for use with an inductively coupled plasma processing system; however other process tools, process conditions and variables may be utilized.

In one embodiment, the processing system 400 may be used to etch a plurality of features within a 1-4 μm thick amorphous carbon layer (ACL) hard mask layer formed above and in contact with one or more underlying layers. As noted above, the ACL hard mask layer may include at least one etch stop layer (ESL), which divides the ACL hard mask layer into two or more portions. The ESL may include a wide variety of etch stop layer materials (such as an oxide, nitride, carbide, metal oxide, metal nitride, metal carbide, other dielectric materials or combinations of layers), and may be deposited to a thickness ranging between a few nm to 100 nm or more.

In some embodiments, a first etch process step may be performed within the processing system 400 to etch the plurality of features within a first portion of the ACL hard mask layer. The first etch process step may have a source power (high frequency) in a range of 1,000-3,000 W, a bias power (low frequency) in a range of 1,000-3,000 W, a pressure in a range of 1-20 mTorr, and a temperature in a range of 10-30 degrees Celsius. Gasses utilized in the first etch process step may include oxygen containing gases (such as O₂) in a range of 200-800 standard cubic centimeters per minute (sccm), sulfur containing gases, such as SO₂ in the range of 100-300 sccm or COS in the range of 10-100 sccm. As noted above, the first etch process may continue until the features etched within slower etch rate (ER) regions of the wafer reach the ESL.

After the features etched within slower ER regions of the wafer reach the ESL, a second etch process step may be performed within the processing system 400 to remove the ESL. The second etch process step may utilize a halogen containing chemistry (such Cl₂, HBr) to remove a metal or Si-containing ESL, or a fluorocarbon (CF) containing chemistry (such as CF₄, CHF₃) to remove other ESLs.

In some embodiments, a third etch process step may be performed within the processing system 400, after the ESL is removed, to etch the plurality of features within a second portion of the hard mask layer. The process conditions used to implement the third etch process step may be identical to the process conditions used to implement the first etch process step. In some embodiments, a single etch stop layer may be formed within ACL hard mask layer, and the third etch process step may continue until the features etched within slower ER regions of the wafer reach the one or more underlying layers. In other embodiments, multiple etch stop layers may be formed within the ACL hard mask layer at various depths, and additional etch process steps may be performed within the processing system 400 to extend the plurality of features through deeper portions of the ACL hard mask layer and to remove each etch stop layer once the features etched within slower ER regions of the wafer reach each etch stop layer.

In some embodiments, a deposition process step may be performed within the processing system 400 to deposit a passivation layer onto sidewalls of the plurality of features after the second etch process step is performed and before the third etch process step is performed. In one embodiment, the deposition process step may utilize an atomic layer deposition (ALD) process or a quasi-ALD process, which uses a silicon precursor gas (such as LTO-520) to deposit a silicon-based passivation layer onto the sidewalls of the features. A typical one cycle ALD process may generally include the following steps: a Si-containing precursor adsorption step, a first purge step, an oxidation step and a second purge step. The above sequence may be repeated for a number of ALD cycles.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

The term “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate including a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

Process steps and methods for etching high aspect ratio features within a hard mask layer are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the described stacked structures, process steps and methods will be apparent to those skilled in the art in view of this description. It will be recognized, therefore, that the described systems and methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for etching features within a hard mask layer of a stacked structure, the method comprising:
forming a stacked structure on a substrate, wherein said forming the stacked structure comprises:
forming a hard mask layer above and in contact with one or more underlying layers; and
forming at least one etch stop layer within the hard mask layer to divide the hard mask layer into two or more distinct portions; and
performing multiple etch processes to etch a plurality of features within the hard mask layer, wherein the plurality of features comprises a first subset of features and a second subset of features, wherein the second subset of features etch at a faster rate than the first subset of features; and
wherein said forming the at least one etch stop layer within the hard mask layer improves etch rate and critical dimension (CD) uniformity of the features etched within the hard mask layer by ensuring that an etch depth of the first subset of features catches up to an etch depth of the second subset of features before the at least one etch stop layer is removed and etching of the hard mask layer resumes.

2. The method of claim 1, wherein said forming the at least one etch stop layer comprises forming a first etch stop layer within the hard mask layer, wherein the first etch stop layer divides the hard mask layer into two distinct portions, and wherein said performing multiple etch processes comprise:
performing a first etch process step to etch the plurality of features within a first portion of the hard mask layer, wherein said performing the first etch process step continues until the first subset of features reaches the first etch stop layer;
performing a second etch process step to remove the first etch stop layer once etching of the first subset of features reaches the first etch stop layer; and
performing a third etch process step to etch the plurality of features within a second portion of the hard mask layer, wherein etching of the first subset of features and the second subset of features proceeds from the same etch depth when the third etch process step begins.

3. The method of claim 2, wherein said performing the second etch process step to remove the first etch stop layer causes a passivation layer to be sputter deposited onto sidewalls of the plurality of features.

4. The method of claim 2, wherein after said performing the second etch process step and before said performing the third etch process step, the method further comprises depositing a passivation layer onto sidewalls of the plurality of features via atomic layer deposition (ALD).

5. The method of claim 2, further comprising continuing the third etch process step until etching of the first subset of features reaches the one or more underlying layers, wherein said forming the first etch stop layer within the hard mask layer reduces CD differences between the features by approximately 50% compared to etch processes that etch features within the hard mask layer without forming the first etch stop layer within the hard mask layer.

6. The method of claim 2, wherein said forming the at least one etch stop layer further comprises forming a second etch stop layer within the hard mask layer, wherein the first etch stop layer and the second etch stop layer divide the hard mask layer into three distinct portions, and wherein said performing multiple etch processes further comprises:
continuing the third etch process step until etching of the first subset of features reaches the second etch stop layer;
performing a fourth etch process step to remove the second etch stop layer once etching of the first subset of features reaches the second etch stop layer; and
performing a fifth etch process step to etch the plurality of features within a third portion of the hard mask layer, wherein etching of the first subset of features and the second subset of features proceeds from the same etch depth when the fifth etch process step begins.

7. The method of claim 6, wherein said performing the fourth etch process step to remove the second etch stop layer causes a passivation layer to be sputter deposited onto sidewalls of the plurality of features.

8. The method of claim 6, wherein after said performing the fourth etch process step and before said performing the fifth etch process step, the method further comprises depositing a passivation layer onto sidewalls of the plurality of features via atomic layer deposition (ALD).

9. The method of claim 6, further comprising continuing the fifth etch process step until etching of the first subset of features reaches the one or more underlying layers, wherein said forming the first etch stop layer and said forming the second etch stop layer within the hard mask layer reduces CD differences between the features by approximately 50-80% compared to etch processes that etch features within the hard mask layer without forming the first etch stop layer and the second etch stop layer within the hard mask layer.

10. The method of claim 1, wherein a thickness of the hard mask layer ranges between 1 μm and 4 μm.

11. The method of claim 1, wherein the plurality of features etched within the hard mask layer each comprise an aspect ratio between 20 to 60.

12. The method of claim 1, wherein said forming the hard mask layer comprises forming a carbon-containing hard mask layer above and in contact with the one or more underlying layers.

13. The method of claim 12, wherein the carbon-containing hard mask layer comprises an amorphous carbon layer (ACL) hard mask layer.

14. The method of claim 12, wherein the one or more underlying layers comprise a dielectric layer, and wherein the carbon-containing hard mask layer is formed above and in contact with the dielectric layer.

15. The method of claim 12, wherein the one or more underlying layers comprise a multilayer vertical stack of alternating layers of dielectric material and conductive material, and wherein the carbon-containing hard mask layer is formed above and in contact with a dielectric material layer of the multilayer vertical stack.

16. A method for etching a pattern of contact holes within a stacked structure included within a three-dimensional (3D) stacked semiconductor memory, the method comprising:
forming the stacked structure on a substrate, wherein said forming the stacked structure comprises:
forming a multilayer vertical stack comprising alternating layers of dielectric material and conductive material;
forming an amorphous carbon layer (ACL) hard mask layer above and in contact with a dielectric material layer of the multilayer vertical stack; and
forming at least one etch stop layer within the ACL hard mask layer to divide the ACL hard mask layer into two or more distinct portions; and
performing multiple etch processes to etch the pattern of contact holes within the ACL hard mask layer, wherein the pattern of contact holes comprises a first subset of contact holes and a second subset of contact holes, wherein the second subset of contact holes etch at a faster rate than the first subset of contact holes; and
wherein said forming the at least one etch stop layer within the ACL hard mask layer improves etch rate and critical dimension (CD) uniformity of the contact holes etched within the ACL hard mask layer by ensuring that an etch depth of the first subset of contact holes catches up to an etch depth of the second subset of contact holes before the at least one etch stop layer is removed and etching of the ACL hard mask layer resumes.

17. The method of claim 16, wherein said forming the at least one etch stop layer comprises forming a first etch stop layer within the ACL hard mask layer, wherein the first etch stop layer divides the ACL hard mask layer into two distinct portions, and wherein said performing multiple etch processes comprise:
performing a first etch process step to etch the pattern of contact holes within a first portion of the ACL hard mask layer, wherein said performing the first etch process step continues until the first subset of contact holes reaches the first etch stop layer;
performing a second etch process step to remove the first etch stop layer once etching of the first subset of contact holes reaches the first etch stop layer; and
performing a third etch process step to etch the pattern of contact holes within a second portion of the ACL hard mask layer, wherein etching of the first subset of contact holes and the second subset of contact holes proceeds from the same etch depth when the third etch process step begins.

18. The method of claim 17, wherein said performing the second etch process step to remove the first etch stop layer causes a passivation layer to be sputter deposited onto sidewalls of the first subset of contact holes and the second subset of contact holes.

19. The method of claim 17, wherein after said performing the second etch process step and before said performing the third etch process step, the method further comprises depositing a passivation layer onto sidewalls of the first subset of contact holes and the second subset of contact holes via atomic layer deposition (ALD).

20. The method of claim 17, further comprising continuing the third etch process step until etching of the first subset of contact holes reaches the dielectric material layer of the multilayer vertical stack, wherein said forming the first etch stop layer within the hard mask layer reduces CD differences between the first subset of contact holes and the second subset of contact holes by approximately 50% compared to etch processes that etch contact holes within the ACL hard mask layer without forming the first etch stop layer within the ACL hard mask layer.

21. The method of claim 16, wherein a thickness of the ACL hard mask layer ranges between 1 μm and 4 μm.

22. The method of claim 16, wherein the first subset of contact holes and the second subset of contact holes etched within the ACL hard mask layer each comprise an aspect ratio between 20 to 60.
